(19) United States
(12) Patent Application Publication
(10) Pub. No.: US 2005/0064338 A1
(43) Pub. Date: Mar. 24, 2005

(54) Natural color targeted printing method

(76) Inventors: Michael Leahy, Grand Rapids, MI (US); Daniel Norman, Rockford, MI (US)

Correspondence Address: PRICE HENEVELD COOPER DEWITT & LITTON, LLP, 695 KENMOOR, S.E., P O BOX 2567, GRAND RAPIDS, MI, 49501, US

(21) Appl. No.: 10/942,424

(22) Filed: Sep. 16, 2004

Related U.S. Application Data
(60) Provisional application No. 60/504,592, filed on Sep. 18, 2003.

(51) Int. Cl. G03F 7/00; G03F 3/08

(52) U.S. Cl. 430/300; 430/301; 358/518

(57) ABSTRACT

A method of producing a quality control device for matching the color, finish or pattern of an item includes determining a plurality of true colors of an item to be matched, the determined colors being anything other than a combination of cyan, magenta, yellow and black. The original product is separated into the plurality of true colors and a random pattern image is generated for each of the plurality of true colors determined. Each of the random pattern images corresponding to each of the true colors generated is transferred onto a printing plate while a plurality of true color inks, correspond in color to the plurality of true colors determined, are provided. The random pattern image transferred to the printing plates is printed onto a substrate, wherein each printing plate prints its corresponding true color ink.

This application claims the benefit of U.S. Provisional Application No. 60/504,592, filed Sep. 18, 2003 entitled STOCHASTIC PRINTING METHOD, which is hereby incorporated herein by reference in its entirety.

### BACKGROUND OF THE INVENTION

The present invention relates to a targeted printing method. More particularly, the method of the present invention uses natural color or non-standard printing ink colors in combination with a targeted (also referred to herein as random) printing method.

The printing method of this invention is an improvement in offset printing. Various approaches to offset printing and related printing methods have long been known in the art. Specifically, conventional offset printing typically involving the use of four traditional process colors (cyan, magenta, yellow, and black) with each color printed at a specific discrete angle with respect to the direction of web or sheet travel in order to represent the color spectrum (see, i.e., FIG. 1), is generally well known in the art and is explained in U.S. Pat. No. 5,283,154 to Stein, which is wholly incorporated herein by reference. Further, as an improvement to the traditional method of offset printing, a randomized method of printing was developed. The randomized method showed promising results in the creation of a higher quality reproduced image as compared with the traditional 4-color process. However, due to the technology of the time, the process was incapable of being represented by a contract proof. Therefore, the only way to predict what the final image would look like was to incur the expense of developing a series of digital files and then creating a press proof from those films.

Generally, the randomized method uses a randomized or dithered placement of ink depositing recesses (herein referred to as dots) in the printing plate rather than the conventional, regularly spaced, angled pattern associated with the usual 4-color screening process (see, i.e., FIG. 2). In addition to the randomization of the dot placement, the randomized method can include the randomization of dot geometry. This randomization in dot placement and/or geometry creates a copied image which is capable of higher resolutions, appears to be clearer, and presents an image with more depth thereby producing a higher quality copied image. The randomized method of printing is generally well known in the art and is also disclosed in U.S. Pat. No. 5,283,154 to Stein.

Nevertheless, there was a problem associated with the randomized method of printing. Due to the lack of sophisticated computer technology when the randomized process was developed, the process was incapable of being quickly and inexpensively represented by a contract proof. A contract proof is a representation of what the final copied image will look like, without the printer having to actually go to press. This allows the customer or end user the ability to determine if the final copied image is acceptable, while allowing the printer a fast and inexpensive method to receive approval from the customer before investing in the time and materials necessary for an actual press run.

In the past, the process for creating a contract proof with the randomized method included transferring the original image to a series of films, each film representing a specific color of the original image. These films were then used to transfer their respective isolated colors to a contract proof film. Finally, the contract proof film was processed to reveal the final contract proof image. Therefore, in order to produce a contract proof, the entire process had to be completed along with the corresponding investment of production costs and time. Additionally, if the customer found the copied image unsatisfactory, the printer was forced to start over and incur a second round of production costs. This process would continue until the customer was satisfied with the image, leaving the printer with excessive production costs. Because a contract proof could not be inexpensively made, the randomized method, even though it produced superior results, was not a commercially acceptable or viable alternative, a characteristic that generally defines a successful printing process.

Another factor which defines a successful printing process is the ability to consistently reproduce an image. Nevertheless, there are applications that are currently incapable of being consistently reproduced using known offset printing processes. Even utilizing the randomized method with its associated superior characteristics, swatch cards or quality control cards are currently not capable of being reproduced accurately enough, nor consistently enough, for the higher end applications in which some of these cards are used.

The printing of color swatches, wood grain swatches, and texture swatches (also called “finishing cards”) have heretofore not been able to be faithfully reproduced using either the conventional 4-color process or the conventional 4-color process in conjunction with the randomized method. This is because these applications require extremely high definition and exacting consistency in order to accurately reproduce the depth and reflection characteristics of the original product.

Color, wood grain, and texture finishing cards are typically used to demonstrate to a customer what color, grain, or texture a manufacturer is capable of producing, or more accurately, reproducing. For example, a manufacturer may manufacture different articles having numerous wood tones and grains. Using the aforementioned finishing cards, the customer is shown a representative sample of these tones and patterns and uses the finishing cards to choose a particular wood tone and grain. When the customer has taken delivery of the manufactured article, the customer may then compare the article to the finishing card supplied by the manufacturer to ensure the appropriate grain, texture, and color has been faithfully reproduced. In addition to the customer using these cards, the manufacturer will typically use these cards as a quality control tool at various stages in the manufacturing process to ensure that the article is precisely matched to the specific grain, texture, and color the customer has chosen.

Because these finishing cards are used by many different people, the actual physical card the customer sees is not likely the same card used in the manufacturing process. Therefore, consistency between these cards ensures the customer receives the same grain, texture, and color which was chosen. Due to the required exacting consistency and high definition, these finishing cards are not capable of being reproduced accurately in a 4-color process using either conventional and/or randomized printing methods in and of themselves. Instead, these finishing cards are usually individually hand fabricated; a fabrication technique which is very expensive.

For example, some of the higher end furniture suppliers use wood tone/grain finishing cards to represent to their customers the exact color and grain pattern they are capable of accurately and consistently reproducing. The customer then, relying on the card for interior design characteristics, requires that the produced articles exactly match the chosen color and grain on the finishing card. Because of the accuracy and consistency that is required in these finishing cards, the cards are currently hand fabricated by a labor intensive staining process. In this process, the chosen wood tone/grain is produced by selecting a representative sample of wood as the substrate and then staining the sample with a series of colors and/or other finishes until the desired wood tone is achieved. This single “grand master” finishing card is then used to gauge all subsequent production. Other “masters” may be produced but they are not exact replicates of the grand master finishing card. This is because the grand master card utilizes a wood product as its substrate which is in and of itself variable in characteristics. It is also hand fabricated which adds even more variability to the process. Therefore, because the grand master card cannot be exactly reproduced, an additional variable is added to the manufacturing process when using the “slightly” different master cards. This can add unwanted variability to the manufacturing process. Additionally, the grand master will age and therefore fade or otherwise change in appearance with time. Still further, this method of fabrication is very time consuming and susceptible to numerous variables, making the process, and thus the finishing cards, very expensive.

Thus, a very high-quality, cost-effective and consistent printing method is sought for these finishing cards.

### BRIEF DESCRIPTION OF THE DRAWINGS

FIG. 1 is a plan view of the traditional four colors used in offset printing and their respective screening angles.

FIG. 2 is a plan view of a random pattern generated by the targeted method for each of the traditional four colors used in offset printing.

FIG. 3 is a block diagram of the printing method of the present invention.

FIG. 4 is a perspective view of a standard four plate printing press.

FIG. 5 is a plan view of the wood tone finishing card of the present invention.

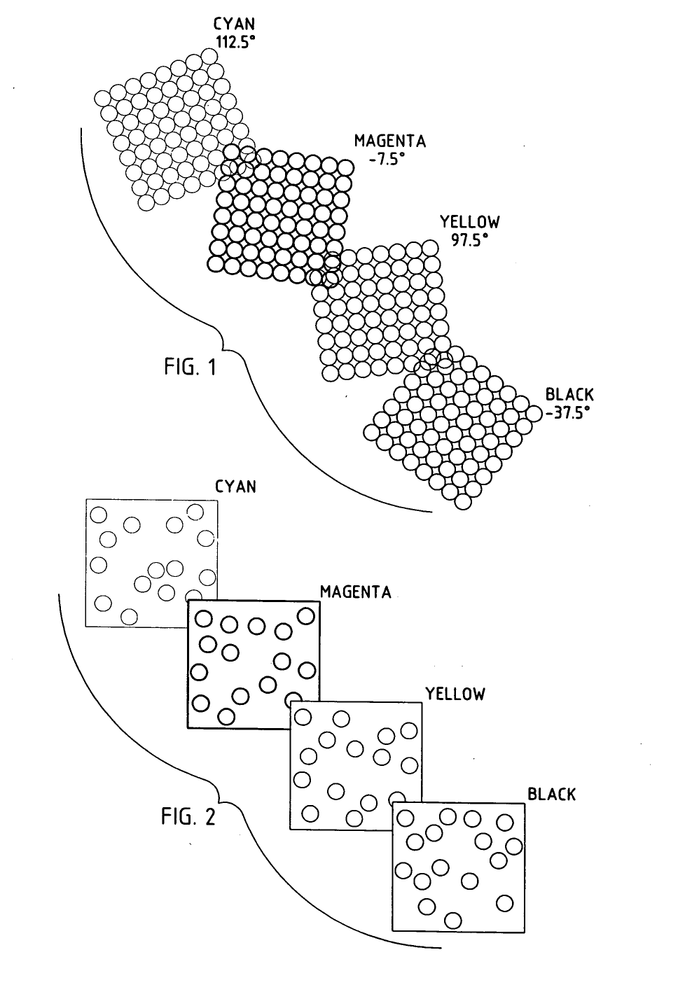

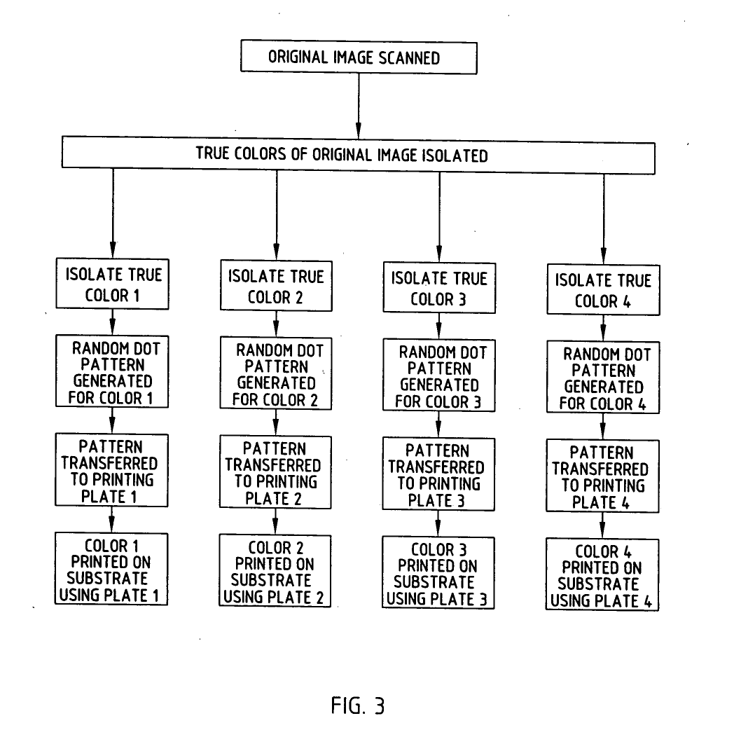

### SUMMARY OF THE INVENTION

In the foregoing, the term “traditional process colors” refers to the traditional four colors used in the offset printing field of cyan, magenta, yellow and black, abbreviated as CMYK. The terms “natural color(s)” and “true color(s)” refer to any solid color other than the combination of the traditional process colors. In other words, “natural colors” is meant to denote the unlimited number of solid colors that can be reproduced using the primary colors of red, yellow and blue, but excludes cyan, magenta, yellow and black. Indeed, cyan, magenta, yellow and black are not used to create a representation of a natural color.

The aforementioned drawbacks and shortcomings of the prior printing methods are elegantly solved with the natural color targeted printing method of the present invention, which provides a cost effective, high quality and consistent reproduced image.

One aspect of the present invention is to provide a method of producing a quality control device for matching the color, finish or pattern of an original item, and includes the steps of: determining a plurality of true colors of an original item to be matched, the determined colors being anything other than a combination of cyan, magenta, yellow and black; separating the color, finish or pattern of the original item into the plurality of true colors; generating a random pattern image corresponding to at least one of the plurality of true colors determined; transferring each of the solid pattern image or the random pattern image corresponding to each of the true colors generated onto a printing plate; providing a plurality of true color inks which correspond in color to the plurality of true colors determined; and printing the random pattern image transferred to the printing plates onto a substrate, each printing plate printing its corresponding true color ink.

Another aspect of the present invention is to provide a method of reproducing an image which includes: generating a plurality of random pattern images for each of a plurality of true colors of an original item to imaged, each generated image corresponding to a particular true color of the original item which is to be imaged; transferring each generated image onto a printing plate; and printing successively each image onto a substrate using a plurality of true color inks, each ink corresponding to the particular true color of the original item, the true colors being anything other than the combination of traditional offset printing process colors of cyan, magenta, yellow and black, each printing plate printing its corresponding true color ink.

Yet another aspect of the present invention is to provide a method of storing a quality control device and includes: electronically determining a plurality of true colors of an original item to be quality controlled; electronically separating the true colors electronically determined, the true colors being anything other than the combination of cyan, magenta, yellow and black; converting the true colors into an electronic from; electronically generating a random pattern image for at least one of the electronically separated true colors; and storing the generated image associated with each of the true colors electronically.

Still another aspect of the present invention is to provide a finishing card made by the process of: isolating the true colors of an original item that is to be imaged, the isolated colors being anything other than the combination of colors from a traditional offset printing process; generating a random pattern image corresponding to one of the isolated true colors; and printing the finishing card using the generated images, each image printing only the corresponding true color that was used for its generation.

Yet another aspect of the present invention is to provide a method of producing a finishing card for matching the color, finish or pattern of an original item, wherein the method includes the steps of: determining a plurality of true colors of an original item to be matched, the determined colors being anything other than a combination of cyan, magenta, yellow and black; separating the color, finish or pattern of the original item into the plurality of true colors; generating a random pattern image corresponding to each of the plurality of true colors determined; transferring each of the random pattern images corresponding to each of the true colors generated onto a printing plate; providing a plurality of true color inks which correspond in color to the plurality of true colors determined; and printing the random pattern image transferred to the printing plates onto a substrate, each printing plate printing its corresponding true color ink.

Still another aspect of the present invention is to provide a finishing card having a wood grain pattern made by the process of: isolating a plurality of true colors of a wood grain on an original item that is to be imaged, the isolated colors being anything other than the combination of colors from a traditional offset printing process; generating one of a random pattern image corresponding to one of the isolated true colors; and printing the finishing card using the generated images, each image printing only the corresponding isolated true color that was used for its generation.

Other advantages and features of the invention will become apparent upon a consideration of the following detailed description, when taken in conjunction with the accompanying drawings. The above brief description sets forth rather broadly the more important features of the present disclosure so that the detailed description that follows may be better understood, and so that the present contributions to the art may be better appreciated. There are, of course, additional features of the disclosure that will be described hereinafter which will form the subject matter of the claims appended hereto.

In this respect, before explaining the preferred embodiment of the disclosure in detail, it is to be understood that the disclosure is not limited in its application to the detail of the construction and the arrangements set forth in the following description or illustrated in the drawings. The above system of the present disclosure is capable of other embodiments and of being practiced and carried out in other ways. Also, it is to be understood that the phraseology and terminology employed herein are for description and not limitation. Where specific dimensional and material specifications have been included or emitted from the specification or the claim, or both, it is to be understood that the same are not to be incorporated into the appended claims.

As such, those skilled in the art will appreciate that the conception, upon which this disclosure is based, may readily be used as a basis for designing other structures, methods, and systems for carrying out the several purposes of the present invention. It is important, therefore, that any claims associated with this application are regarded as including such equivalent constructions as far as they do not depart from the spirit and scope of the present invention.

Further, the purpose of the abstract is to enable the United States Patent and Trademark Office and the public generally, and especially the scientists, engineers and practitioners in the art who are not familiar with the patent or legal terms of phraseology, to learn quickly from a cursory inspection the nature and essence of the technical disclosure of the application. Accordingly, the abstract is intended to define neither the invention nor the application, which is only measured by the claims, nor is it intended to be limiting as to the scope of the invention in any way.

These and other aspects of the invention, along with the various features and structures that characterize the invention, are pointed out with particularity in any claim annexed to and forming a part of this disclosure. For a better understanding of the printing method of the present disclosure, its advantages and the specific objects attained by its uses, reference should be had to the accompanying drawings and descriptive matter in which there are illustrated and described the preferred embodiments of the invention.

While embodiments of the printing method are herein illustrated and described, it is to be appreciated that various changes, rearrangements and modifications may be made therein, without departing from the scope of the invention as defined by any claims annexed to and forming a part of the disclosure.

### DETAILED DESCRIPTION OF THE PREFERRED EMBODIMENTS

The best mode for carrying out the invention is presented in terms of the preferred embodiment.

Introduction

Generally, the improved method of the present invention is realized in the following steps. Initially, the image to be reproduced is scanned in order to determine and correspondingly separate the particular true or natural colors of the original image or product. Preferably, for each of the plurality of natural colors separated, a random pattern of dots is generated. In the preferred embodiment, a solid pattern or flood coat is used to achieve a base upon which the random patterns are subsequently printed. However, this is only the preferred embodiment and more flood coats may be used. Alternatively, the random pattern may be the only pattern that is used, or the random patterns and flood coats may be combined with a conventional screening process.

Each of the solid pattern and random dot pattern images are then transferred to a printing plate with each printing plate representing and using a single natural color. With respect to the solid patterns, the “image” is not transferred to the plate but, for example, in a press that utilizes water, the water may be turned off allowing all areas of the plate access and adherence to the ink, thereby creating a uniform solid flood coat. Finally, the printing plates are used to successively print or lay down each natural color of the separated image to reproduce a high quality and consistent reproduction of the true image or product.

The scanning of an image or product in order to determine and correspondingly separate the true colors of the image or product is generally well known in the art and does not form a part of this inventive concept. For each of the plurality of natural colors separated, a random pattern of dots is generated and again the methods for so doing are generally well known in the art. Non-standard, natural or true color inks are used in combination with either a solid pattern and random dot pattern, which is created specifically for each of the natural colors, in order to achieve superior printing detail.

The solid pattern or flood coat is a non-patterned layer of a particular natural color or colors which floods or coats the substrate to which it is applied. It is typically used to provide a layer of uniform color on the substrate thereby providing a foundation for subsequent printing. Alternatively, the random patterns do not cover the entire surface but are unique and represent a portion of an image associated with a specific natural color. Additionally, as described previously the random patterns do not use the standard screen angle associated with the traditional 4-color printing process. Instead, the random pattern uses the frequency of the dots on the image to control respective areas of density or contrast, thereby defining the image.

Determination and Separation of Natural Colors

More particularly, the determination of the particular natural colors of the true image can be accomplished through various means and is generally known in the art. For example, using a computer, the original image or product may be electronically scanned and a software program having the ability to represent the separated natural colors in electronic form can be used to isolate and then determine each particular natural color of the original. Importantly, the natural colors that are determined and represented in electronic form are the true or natural colors of the original product and are not simply a representation of the natural color utilizing the four traditional process colors of CMYK.

Additionally, a novel approach has been invented to determine a particular natural color. In the past, a computer represented a particular color by utilizing the four process colors of CMYK and/or the over 800 colors of the Pantone® Matching System Color Chart. However, in order to determine what a desired color would look like using only natural colors, the desired color would have to be actually made. This process was very subjective and relied on skilled personnel. The process consisted of mixing natural colors together and qualitatively examining the resultant color until the final desired color was achieved. However, the colorant can change depending upon the substrate used and therefore, as a final step, an experimental run was processed in order to determine if the desired color actually matched the original color it was designed to replicate. This process was repeated until the desired natural color was achieved.

In order to reduce the time and effort that was associated with this activity, a computer program was developed that allows the original color to be either scanned in or selected from a list. The computer then determines the ratios of specific colors that are needed in order to reproduce this color. However, instead of selecting a color from either a Pantone® or a CMYK reference, the computer is provided with a palette of natural colors, determined and entered previously. Therefore the desired color can be more accurately represented by selecting ratios of colors from the palette of natural colors. Nevertheless, the computer may simultaneously utilize the Pantone® or CMYK colors for enhanced matching ability. The desired color may then be edited by adjusting certain parameters such as, for example only, color, brightness, contrast, hue, and saturation. This allows the natural color to be changed without having to proceed with an experimental run.

Further, metamerism, which occurs when color samples appear to match under one light condition but not under another, is reduced with this program by allowing the spectral curves of the original and desired colors to be superimposed and therefore analyzed together. It is generally understood that as the spectral curves of two colors decrease in the number of intersections, metamerism is decreased. Preferably, the spectral graphs will intersect three or less times for optimum reduction in metamerism. The desired color can be changed (as described above) to reduce the number of intersections of the corresponding spectral graphs while simultaneously allowing the end user the ability to see the associated change in color that results. This trial and error approach allows the optimum natural color to be chosen without ever having to actually mix any ink.

After determination of the particular natural colors of an image, the original product is then separated into a plurality of images, each image representing the portion of the original which consists of, or is made up of, the particular natural color determined in the previous step; the plurality of single natural color images, in combination, creating the original product or image. The separation of the true image into a plurality of natural colors can be accomplished by various methods. However, and for example only, this may be accomplished using a software program such as Photo Shop@, published by Adobe.

Pattern Generation

After the determination of the particular natural colors and their separation, a random dot pattern image is generated for any separated natural color requiring a random pattern. In addition, a solid pattern, also known as a flood coat, may be generated for a separated natural color.

Generating the random dot pattern for a particular isolated color of an image and subsequently printing that pattern on a printing plate is referred to as the targeted printing method. In the targeted method, there are generally two variables which may be varied in order to achieve the desired results. The first variable is the randomization of the dot pattern to accomplish darker and lighter areas of an image. This is accomplished by targeting more dots in an area of the image which is to be darker in appearance and less in the areas which are to appear lighter.

As the second variable beyond the randomization of the dot pattern, the dot geometry may also be randomized in order to achieve the same results. With the randomization of dot geometry, the geometry of the dot is used to create corresponding light and dark areas. Larger dot size is associated with areas that are to appear darker and smaller dot size is associated with areas that are to appear lighter. Of course, both variables may be randomized or varied concurrently to achieve the desired results. The method of the present invention may utilize, either individually or in combination, both of these variables. However, in the preferred embodiment only the dot pattern is randomized.

With respect to the flood coat, the solid pattern is a non-patterned layer of at least one particular natural color which floods or coats the substrate to which it is applied. It is typically used to provide a layer of uniform color on the substrate thereby providing a foundation for subsequent printing. For example, in the preferred embodiment, multiple flood coats are used in succession to print a base that has the color of or represents the natural color and tone of real wood.

Printing

The dot pattern generated for a particular natural color is then transferred onto a printing plate. The methods for doing this are generally well known in the art. Additionally, a printing plate or plates may be set up in the press to print a flood coat as described above. Each of the plurality of printing plates are then transferred and installed in the press and each plate will correspond to a single natural color.

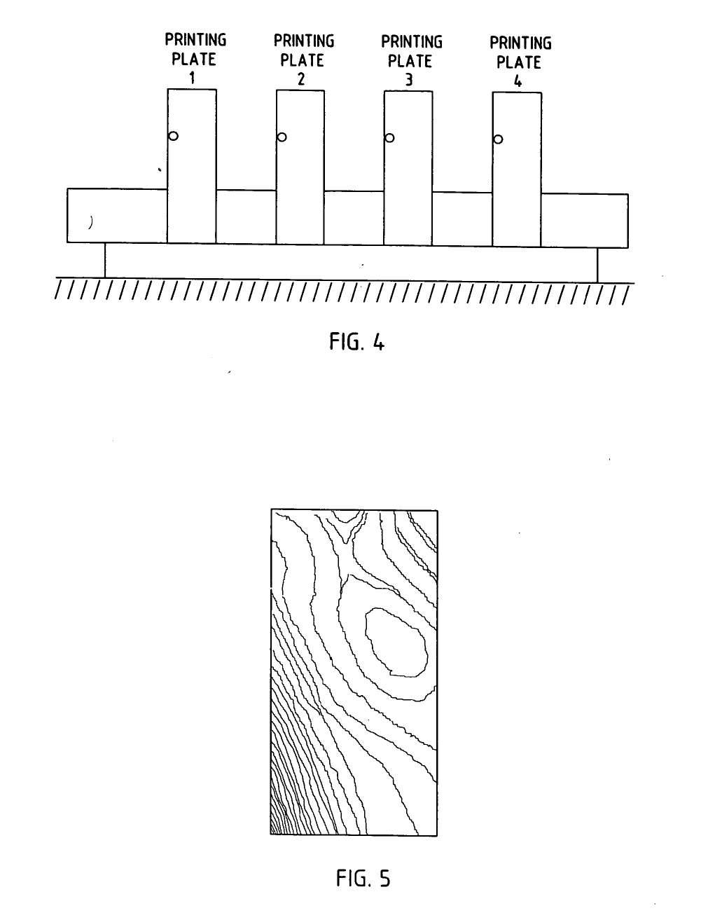

Finally, the printing plates are used successively in the printing process in order to reproduce the original product (FIG. 4). This is accomplished by printing either the flood coat or the random dot pattern associated with each of the natural colors in succession, with each plate printing its particular natural color over the previous plate's image.

In the preferred embodiment, a wood tone finishing card is created by initially using at least the first plate to create the wood grain pattern on the substrate. Subsequently, the other plates are used to successively print a targeted or random pattern on the wood grain. Each plate laying its pattern and color over the previous plates image in order to build the depth and reflectivity that is associated with the real wood product while taking into consideration the color of stains used in the wood manufacturing process. This results in a reproduced image that accurately represents the depth and reflectivity of the original product. However, this is only the preferred embodiment and any plate may be used to create the wood grain pattern. Further, the order of the printing of these layers is not meant to be limiting in any manner. The methods and machines for using a printing press in order to achieve a desired reproduced image are generally well known in the art and do not form a part of the inventive concept of the current invention. Rather, the inventive concept lies with at least one printing plate with a random dot pattern being associated with and printing only natural colors. That is to say, the process does not utilize the four traditional process colors of CMYK to create a representation of another color. Rather, the printing plates use natural colors and may be combined with additional plates that use the standard 4-color process. In the preferred embodiment, all the plates in the process each utilize a single natural or true color, where each color is successively laid down onto the substrate to combine and form a highly defined and consistent representation of the true or original product.

Conventionally, the randomized method of printing, which utilizes the traditional four process colors, was ineffective as a printing process due to the inability to create an inexpensive contract proof. Therefore, the conventional randomized method was not able to cost effectively reproduce images. As such, further investigation and development was not conducted on this process. This is especially true with respect to non-standard colors. If the process was not capable of producing predetermined definable results using only four colors, then there was no expectation of success with the process using an unlimited number of color hues.

Therefore, none of the prior existing methods were known to combine a randomized method of printing, including one or both of a randomized dot pattern or randomized dot geometry, with the use of non-standard natural or real tone colors to achieve a desired reproduced image. Further, it has heretofore been unknown to utilize the additional step of a flood coat with the above random patterns. Still further, this inventive concept has apparently never been used before in order to reproduce finishing cards or swatches which represent a specific color, a specific grain pattern, and/or specific texture (FIG. 5).

When these cards or swatches function as quality control documents or representations of a particular color, grain, or texture, the consistency between each of the reproduced cards is crucial. Additionally, these cards or swatches must not degrade for a set period of time and must remain in their original color, grain, and texture, in order to accurately represent the original article the card was designed to reproduce.

The advantages of using the randomized method in conjunction with true or natural colors of an image include: (1) more accurately reproducing an original product with regard to its color, grain, or texture; (2) providing consistency between the reproduced images compared to any other printing process; (3) using natural or true colors to print the reproduced image, where use of a true color rather than a representation of a color produces colors that tend to be more colorfast; (4) reducing the cost to reproduce these quality control cards or swatches with regard to current manufacturing methods; (5) reducing the process time associated with creating these quality control cards or swatches; and (6) producing a more accurate representation of color depth, hue, reflectivity and range.

The solutions offered by the invention herein have thus been attained in an economical, practical, and facile manner. To wit, an effective and convenient printing method utilizing a randomized dot pattern and natural colors. While preferred embodiments and example configurations of the invention have been herein illustrated, shown and described, it is to be appreciated that various changes, rearrangements and modifications may be made therein, without departing from the scope of the invention as defined by any appended claims. It is intended that the specific embodiments and configurations disclosed are illustrative of the preferred and best modes for practicing the invention, and should not be interpreted as limitations on the scope of the invention as defined by any appended claims and it is to be appreciated that various changes, rearrangements and modifications may be made therein, without departing from the scope of the invention as defined by any appended claims.

1. A method of producing a quality control device for matching the color, finish or pattern of an original item, the method including the steps of:
determining a plurality of true colors of an original item to be matched, the determined colors being anything other than a combination of cyan, magenta, yellow and black;
separating the color, finish or pattern of the original item into the plurality of true colors;
generating a random pattern image corresponding to at least one of the plurality of true colors determined;
transferring each of the solid pattern image or the random pattern image corresponding to each of the true colors generated onto a printing plate;
providing a plurality of true color inks which correspond in color to the plurality of true colors determined; and
printing the random pattern image transferred to the printing plates onto a substrate, each printing plate printing its corresponding true color ink.

2. The method according to claim 1, wherein:
the determining step is done electronically.

3. The method according to claim 1, wherein:
the generating step includes generating a random pattern having a random dot pattern; and
the random dot pattern is generated electronically.

4. The method according to claim 3, wherein:
the generated random dot pattern includes generating a dot pattern having a random geometry.

5. The method according to claim 1, wherein:
the transferring step includes transferring only random pattern images to the printing plates; and
the printing step includes printing only the random pattern image onto the substrate.

6. The method according to claim 1, wherein:
the printed substrate is a finishing card that is used, at least in part, to match at least one of the true colors of the original item, which is to be quality controlled.

7. The method according to claim 1, wherein:
the printed substrate is a finishing card wherein the finishing card used, at least in part, to match a pattern of the original item, which is to be quality controlled.

8. The method according to claim 1, wherein:
the printed substrate is a color swatch.

9. The method according to claim 1, wherein:
the printed substrate is a wood grain swatch.

10. The method according to claim 1, wherein:
the printing in the printing step is done on a waterless printing press.

11. The method according to claim 1, wherein:
the generating step includes generating a solid image for at least of the determined plurality of true colors.

12. A method of reproducing an image comprising:
generating a plurality of one of random pattern images for each of a plurality of true colors of an original item to imaged, each generated image corresponding to a particular true color of the original item which is to be imaged;
transferring each generated image onto a printing plate; and
printing successively each image onto a substrate using a plurality of true color inks, each ink corresponding to the particular true color of the original item, the true colors being anything other than the combination of traditional offset printing process colors of cyan, magenta, yellow and black, each printing plate printing its corresponding true color ink.

13. The method according to claim 12, including:
electronically determining the particular true colors of the original item.

14. The method according to claim 12, wherein:
the generating step includes generating a random pattern having a random dot pattern; and
the random dot pattern is generated electronically.

15. The method according to claim 14, wherein:
the generated random dot pattern includes generating a dot pattern having a random geometry.

16. The method according to claim 12, wherein:
the transferring step includes transferring only random pattern images to the printing plates; and
the printing step includes printing only the random pattern image onto the substrate.

17. The method according to claim 12, wherein:
the printed substrate is a quality control card used, at least in part, to match at least one of the true colors of the original item, which is to be quality controlled.

18. The method according to claim 12, wherein:
the printed substrate is a quality control card used, at least in part, to match a pattern of the original item, which is to be quality controlled.

19. The method according to claim 12, wherein:
the printed substrate is a color swatch.

20. The method according to claim 12, wherein:
the printed substrate is a wood grain swatch.

21. The method according to claim 12, wherein:
the generating step includes generating a flood coat.

22. A method of storing a quality control device including:
electronically determining a plurality of true colors of an original item to be quality controlled;
electronically separating the true colors electronically determined, the true colors being anything other than the combination of cyan, magenta, yellow and black;
converting the true colors into an electronic from;
electronically generating a random pattern image for at least one of the electronically separated true colors; and
storing the generated image associated with each of the true colors electronically.

23. The method according to claim 23, wherein:
the electronically determining step includes electronically determining the true colors by scanning.

24. The method according to claim 23, wherein:
the storing step includes storing the true colors digitally.

25. The method according to claim 23, wherein:
the electronically generating step includes generating a random pattern having a random dot pattern.

26. The method according to claim 26, wherein:
the generated random dot pattern includes generating dots having a random geometry.

27. The method-according to claim 23, wherein:
the electronically generating step includes generating a flood coat.

28. A finishing card made by the process of:
isolating the true colors of an original item that is to be imaged, the isolated colors being anything other than the combination of colors from a traditional offset printing process;
generating a random pattern image corresponding to one of the isolated true colors; and
printing the finishing card using the generated images, each image printing only the corresponding true color that was used for its generation.

29. The card according to claim 29, wherein:
the isolation of the true colors is done electronically.

30. The card according to claim 29, wherein:
the random pattern is generated electronically.

31. The card according to claim 29, wherein:
the generated random pattern further includes a random geometry.

32. The card according to claim 29, wherein:
all of the generated pattern images are random pattern images.

33. The card according to claim 29, wherein:
the finishing card is a quality control device for matching, at least in part, at least one true color of an original item to be quality controlled.

34. The card according to claim 29, wherein:
the finishing card is a quality control device for matching, at least in part, the pattern of an original item to be quality controlled.

35. The card according to claim 29, wherein:
the finishing card is a color swatch.

36. The card according to claim 29, wherein:
the finishing card is a wood grain swatch.

37. The card according to claim 29, wherein:
the generating step includes generating a solid image for at least one of the isolated true colors.
